(19) United States
(12) Patent Application Publication
(10) Pub. No.: US 2001/0023494 A1
(43) Pub. Date: Sep. 20, 2001

(54) BIP-N processing apparatus and BIP-N processing method therefor

(75) Inventors: Akinori Miyazaki, Miyagi (JP); Kazunori Shin'ya, Tokyo (JP)

Correspondence Address: OSTROLENK, FABER, GERB & SOFFEN, 1180 AVENUE OF THE AMERICAS, NEW YORK, NY, 10036-8403, US

(73) Assignee: NEC Corporation

(21) Appl. No.: 09/808,065

(22) Filed: Mar. 14, 2001

(30) Foreign Application Priority Data
Mar. 15, 2000 (JP) 072046/2000

(51) Int. Cl. H03M 13/03

(52) U.S. Cl. 714/752

(57) ABSTRACT

In a Bit Interleaved Parity (BIP)-N calculating apparatus (N is an integer) according to the present invention, serial/parallel conversion circuit 1 performs a byte-interleaved separation on input STS-3c concatenated signals. The separated signals are supplied to the serial/parallel conversion circuits 2 to 4 where these signals are subjected to a bit-interleaved separation to attain N-bit signals. Each serial/parallel conversion circuit respectively provides the N-bit signal to BIP-N calculation circuit 5 to 7. Outputs from the BIP-N calculation circuit 5 to 7 are held in flip-flops 8 to 10 and then supplied to exclusive-OR gates 11 to 13. The exclusive-OR gates 11to 13 and concatenation control circuits 14 to 16 are connected in a concatenation manner, so that a calculation is performed in a concatenation manner on the results of the BIP-N calculation circuits 5 to 7. The EX-OR gate 11 outputs a signal as the BIP-N calculation result.

### BACKGROUND OF THE INVENTION

The present invention relates to a Bit Interleaved Parity (BIP)-N calculating apparatus and a BIP-N calculating method used in the apparatus, particularly, to a method of performing a BIP-N calculation used for supervising various main signals when executing a signal transmission by using a Synchronous Digital Hierarchy (SDH) transmission method.

Conventionally, when performing a signal transmission in a Synchronous Optical Network (SONET) and by the use of an SDH transmission method, various main signals are supervised. One of well-known methods of the signal supervision is that the BIP-N calculation (N is an integer) is applied to one signal (the whole of one frame) and a performance monitor is executed by comparing the calculation results with data encapsulated in the subsequent frame. For the purpose of monitoring the signal, the BIP-N calculation is performed in block by one calculation circuit with respect to one signal.

As a transmission rate becomes higher, and high-capacity concatenated signals are required for transmitting high-capacity data, it is necessary for a calculation circuit to perform a signal processing at a higher rate or in a parallel manner.

Japanese laid-open patent application 5-300116 discloses a technique of performing a BIP-8 calculation by reordering bits. FIG. 6 shows by way of example a block diagram of a prior art BIP-N calculation circuit with respect to concatenated signals.

As shown in FIG. 6, serial/parallel conversion circuits S/P (1) to S/P (24) as respectively denoted with reference numerals 31-1 to 31-24, perform a bit-interleaved separation on input Synchronous Transport Signal (STS)-1 signal #1 to STS-1 signal #24, DATA with a rate of 51.84 Mbps, to obtain respective N-bit signals. Signals which have been subjected to a bit-interleaved separation in the serial/parallel conversion circuits 31-1 to 31-24, are assembled to parallel/serial conversion circuits P/S (1) to P/S (8) as respectively denoted with numerals 32-1 to 32-8, in corresponding bit units from a Most Significant Bit (MSB) to a Least Significant Bit (LSB).

In the technique described in the laid-open patent application, the BIP-N calculation is performed with respect to STS-3c signals #1 to #8, DATA with a rate of 155.52 Mbps, which have been multiplexed by the parallel/serial conversion circuits 32-1 to 32-8. More specifically, the prior art technique is related to a circuit that is used for calculating the value of B3 (an even parity) of a Path OverHead (POH) with respect to a Virtual Container (VC)-32 frame (a BIP-N code) in a transmission network performing a transmission at a synchronous interface rate defined by the SDH, and for adding and checking the value.

In the prior-art technique as illustrated above, the more the capacity of concatenated signals, the higher the rate of signals generated in the parallel/serial conversion circuit. It is therefore necessary to speed up the BIP-N calculation circuit. In a case of STS-48c concatenated signals, for example, the signals consist of 48 STS-1 signals, resulting in signals output from the parallel/serial conversion circuit to be 311.04 Mbps, which is twice as high as that of the STS-3c concatenated signals.

The prior-art technique as set forth above has another problem that the circuit becomes larger in size and complicated in structure. In other words, the prior-art technique requires the serial/parallel conversion circuits and parallel/serial conversion circuits for forming one serial signal for every corresponding bit by reordering bits, and for performing the BIP-N calculation on the serial signal. Furthermore, the high-capacity concatenated signals can not be obtained by one serial signal with respect to the corresponding bit, thus requiring a plurality of signals. Accordingly, the BIP-N calculation circuit becomes complicated in structure.

### SUMMARY OF THE INVENTION

In view of the foregoing problem, it is an object of the present invention to provide a BIP-N calculating apparatus and a BIP-N calculating method used in the apparatus, which enables to perform the BIP-N calculation with respect to concatenated signals in a simple structure and lets the structure to be easily expanded in accordance with the kind of concatenated signals.

According to the present invention, there is provided a Bit Interleaved Parity (BIP)-N calculating apparatus comprising: separating means for performing a byte-interleaved separation on concatenated signals with respect to input synchronous transport signals to obtain a plurality of signals separated by the byte interleaving; a plurality of BIP-N calculating circuits for executing a bit interleaved parity (BIP)-N calculation on each of said plurality of signals; and a logical operation means for carrying out a logical operation on each calculation result of said plurality of BIP-N calculating circuits.

The invented method of calculating a Bit Interleaved Parity (BIP)-N (N is an integer) comprises the steps of: performing a byte-interleaved separation on concatenated signals with respect to input synchronous transport signals to obtain a plurality of signals separated by the byte interleaving; executing a bit interleaved parity (BIP)-N calculation on each of said plurality of signals; and carrying out a logical operation on the results of said BIP-N calculation.

Bit Interleaved Parity (BIP)-N calculation according to the present invention is characterized by a simple construction which provides the BIP-N calculation with respect to concatenated signals in the SONET and SDH transmission methods. More specifically, in the BIP-N calculation according to the present invention, a byte-interleaved separation is performed on input STS-3c concatenated signals via serial/parallel conversion circuit (S/P) to obtain three STS-1 signals, STS-1 signals #1 to #3. Each STS-1 signal is subjected to operation by BIP-N calculation circuit and the calculation results regarding each of the STS-1 signals #1 to #3 are exclusive-ORed. This results in performance of an exclusive-OR operation on all of the first STS-1 signal #1 through the third STS-1 signal #3, thus obtaining the BIP-N calculation results with respect to STS-3c concatenated signals.

In other words, in the present invention BIP-N calculation, concatenation control circuits and exclusive-OR gates are connected in a concatenation manner, so that a calculation is also performed in a concatenation manner on the results of the BIP-N calculation circuits. The concatenated signals are subjected to a byte-interleaved separation to obtain STS-1 signals, and a BIP-N calculation is performed on each of the STS-1 signals. The present invention therefore provides a simple construction to execute the BIP-N calculation with respect to the concatenated signals. Furthermore, the apparatus according to the present invention has a construction capable of being easily expanded in conformity with the kind of concatenated signals.

### BRIEF DESCRIPTION OF THE DRAWINGS

FIG. 1 is a block diagram of a BIP-N calculation apparatus according to an embodiment of the present invention;

FIG. 2 is a block diagram illustrating by way of example a construction of the concatenation control circuit 16 of FIG. 1;

FIG. 3 is a diagram depicting STS-3c concatenated signals which are input to serial/parallel conversion circuit of FIG. 1;

FIG. 4A is a diagram showing STS-1 signal #1 which has been subjected to a byte-interleaved separation in the serial/parallel conversion circuit 1 of FIG. 1;

FIG. 4B shows STS-1 signal #2 which has been subjected to a byte-interleaved separation in the serial/parallel conversion circuit 1 of FIG. 1,

FIG. 4C illustrates STS-1 signal #3 which has been subjected to a byte-interleaved separation in the serial/parallel conversion circuit 1 of FIG. 1;

FIG. 5 is a sequence chart depicting a processing performed by a BIP-N calculation apparatus according to the present embodiment; and

FIG. 6 shows by way of example a block diagram of a prior art BIP-N calculation circuit with respect to concatenated signals.

### DESCRIPTION OF THE PREFERRED EMBODIMENTS

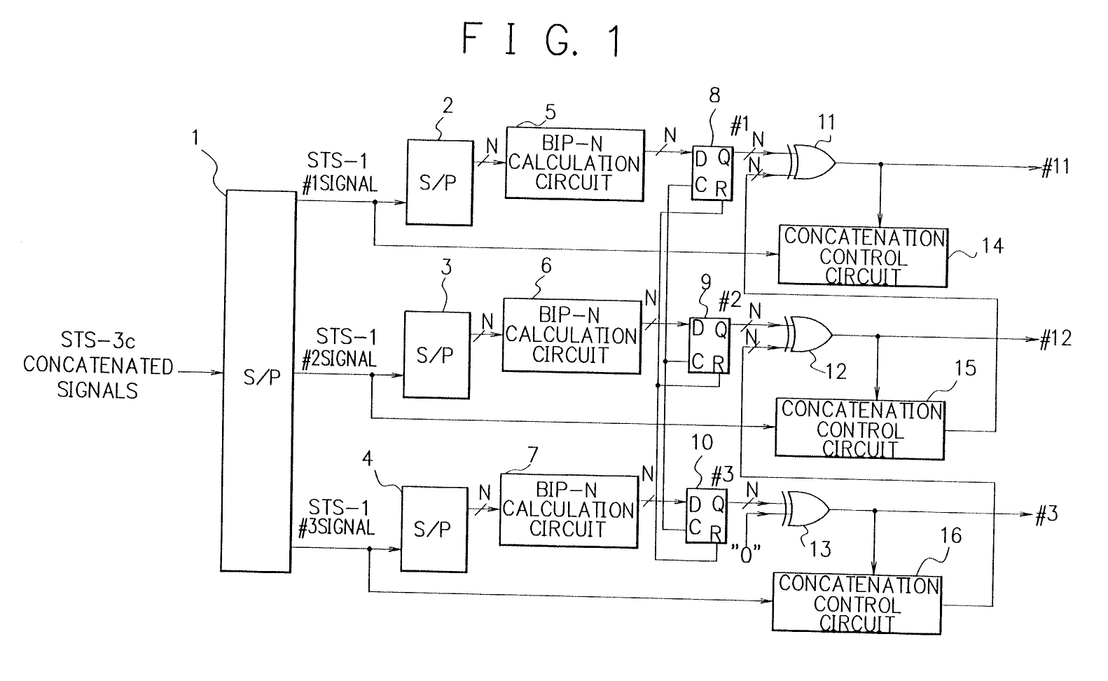

Description will now be given of an embodiment of the present invention by referring to the drawings. FIG. 1 is a block diagram of a BIP-N calculation apparatus (N is an integer) according to an embodiment of the present invention. As shown in FIG. 1, the BIP-N calculation apparatus according to the present embodiment comprises serial/parallel (S/P) conversion circuits 1 to 4, BIP-N calculation circuits 5 to 7, flip-flops (hereinafter referred to as F/F) 8 to 10, exclusive-OR (EX-OR) gates 11 to 13, and concatenation control circuits 14 to 16.

Serial/parallel conversion circuit 1 performs a byte-interleaved separation on input STS-3c concatenated signals to obtain three STS-1 signals, STS-1 signal #1 to STS-1 signal #3, which are then supplied to the serial/parallel conversion circuits 2 to 4, respectively. Signals input to the serial/parallel conversion circuits 2 to 4 are subjected to a bit-interleaved separation to attain N-bit signals (N is an integer). The serial/parallel conversion circuits respectively provide the N-bit signal to the BIP-N calculation circuits 5 to 7.

It should be noted that the serial/parallel conversion circuit 1 may be modified according to the concatenated signals. Similarly, the serial/parallel conversion circuits 2 to 4 may be changed according to the number N with respect to a bit-interleaved separation.

The BIP-N calculation circuits 5 to 7 check the parity of signals which have been subjected to a bit-interleaved separation in the serial/parallel conversion circuits 2 to 4. Outputs from the BIP-N calculation circuit 5 to 7 are held in the respective F/Fs 8 to 10 whose outputs are then sent to the EX-OR gates 11 to 13.

The results of a BIP-N calculation with respect to the third STS-1 signal (STS-1 signal #3) and 0 (zero) are input to the EX-OR gate 13. The output of the EX-OR gate 13 is supplied to the EX-OR gate 12 via the concatenation control circuit 16. The output of the EX-OR gate 12 is input to the EX-OR gate 11 via the concatenation control circuit 15. Finally, the EX-OR gate 11 outputs a signal as the BIP-N calculation result concerning the STS-3c concatenated signal.

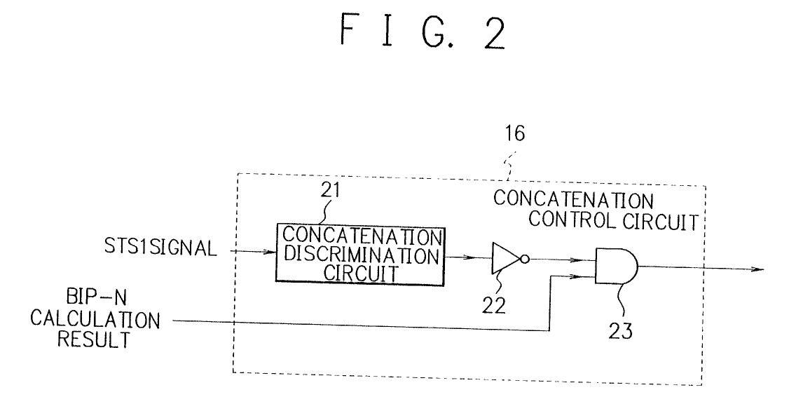

FIG. 2 is a block diagram illustrating by way of example a construction of the concatenation control circuit 16 of FIG. 1. As shown in FIG. 2, the concatenation control circuit 16 includes a concatenation discrimination circuit 21, an inverter gate 22, and an AND gate 23 which performs a logical AND operation. All of which are gate circuits with a simple structure. The concatenation control circuits 14 and 15 have the same structure as that of the concatenation control circuit 16. Therefore, the concatenation control circuit 16 is taken for example in the following description.

The concatenation discrimination circuit 21 identifies whether the input STS-1 signal is the first STS-1 signal or the second STS-1 signal or the third STS-1 signal, thus providing a discrimination signal to the inverter gate 22. The output lead of the inverter gate 22 is connected to one of the leads of the AND gate 23. The output of the EX-OR gate 13 corresponding to the input STS-1 signal is connected to the remaining lead of the AND gate 23. The output from the AND gate 23 therefore signifies the output of the concatenation control circuit 16. In the example as shown in FIG. 2, if the concatenation discrimination circuit 21 identifies the input signal as the first STS-1 signal, the circuit 21 outputs a logical “1”. If the input signal is the second or the third STS-1 signal, the circuit 21 outputs a logical “0”.

As a result, the concatenation control circuit 16 has a structure where the output of the AND gate 23 (which is also the output from the circuit 16) is “0” for the first STS-1 signal, and where the input from the EX-OR gate 13 is output as is, for the second or third STS-1 signal. It should be noted that as far as the output from the concatenation control circuit 16 maintains the above-mentioned logic, the inverter gate 22 and AND gate 23 may be modified according to the logic of the discrimination signal in the circuit 16.

Operation of the BIP-N calculation apparatus according to the embodiment of the present invention will be described with reference to FIGS. 1 and 2. As mentioned above, the serial/parallel conversion circuit 1 performs a byte-interleaved separation on input STS-3c concatenated signals so as to obtain three STS-1 signals, STS-1 signals #1 to #3. The first STS-1 signal #1 is supplied to the serial/parallel conversion circuit 2, the second STS-1 signal #2, to the serial/parallel conversion circuit 3, and the third STS-1 signal #3, to the serial/parallel conversion circuit 4.

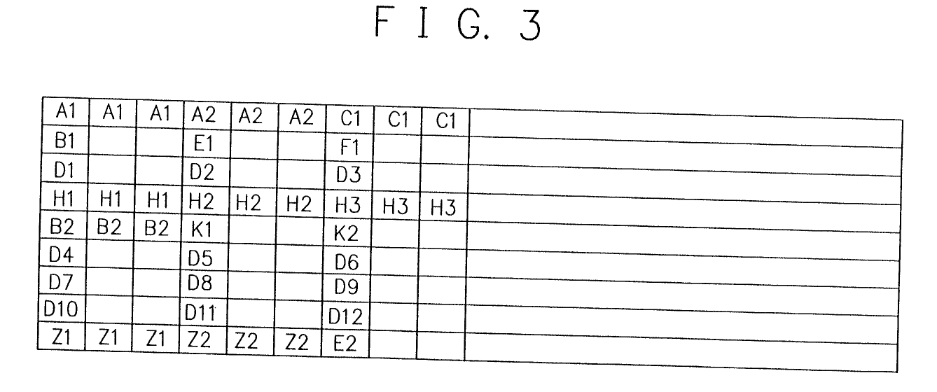

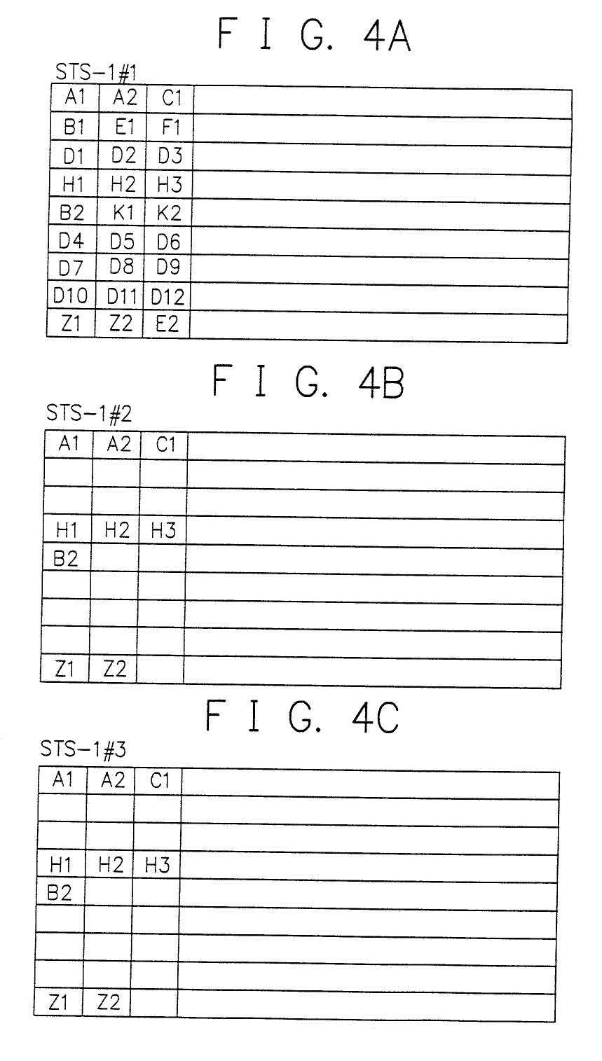

FIG. 3 is a diagram depicting STS-3c concatenated signals which are input to the serial/parallel conversion circuit 1. FIG. 4A is a diagram showing the STS-1 signal #1 which has been subjected to a byte-interleaved separation by the serial/parallel conversion circuit 1 of FIG. 1, FIG. 4B, the STS-1 signal #2 subjected to a byte-interleaved separation by the serial/parallel conversion circuit 1, and FIG. 4C, the STS-1 signal #3 subjected to a byte-interleaved separation by the serial/parallel conversion circuit 1.

When the STS-3c concatenated signals as shown in FIG. 3 are input to the serial/parallel conversion circuit 1, the circuit 1 performs a byte-interleaved separation on these concatenated signals to obtain the STS-1 signals #1, #2, and #3, as respectively shown in FIGS. 4A, 4B, and 4C. The STS-1 signals #1, #2, and #3 are input to respective serial/parallel conversion circuits 2 to 4. These circuits 2 to 4 then output N signals (N is an integer) which have been subjected to a bit-interleaved separation, to the BIP-N calculation circuits 5 to 7, respectively.

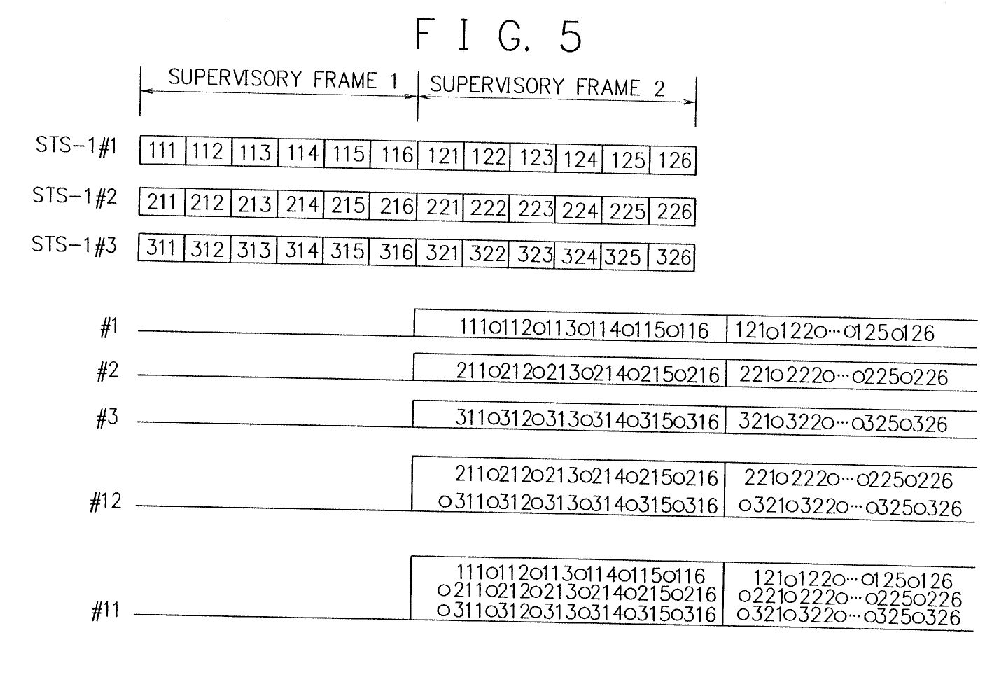

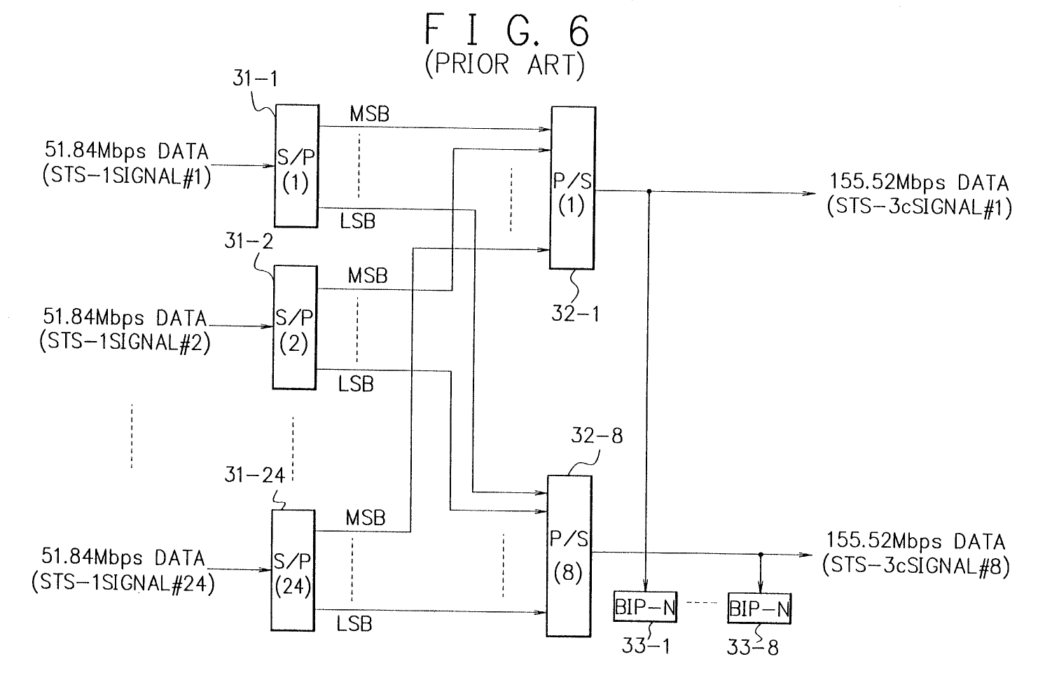

FIG. 5 is a sequence chart depicting a processing executed by a BIP-N calculation apparatus according to the present embodiment. As shown in FIG. 5, STS-1 signal #1 is an input signal to the BIP-N calculation circuit 5, STS-1 signal #2 to the BIP-N calculation circuit 6, and STS-1 signal #3 to the BIP-N calculation circuit 7.

If a supervisory frame $1 of the STS-1 signal #1 is subjected to a logical exclusive-OR operation, the result #1($1) is expressed as:

#1($1)=111∘112∘113∘114∘115∘116 (1)

where ∘ indicates a symbol of the exclusive-OR operation.

Similar to the STS-1 signal #1 as shown above, if a supervisory frame $1 of the STS-1 signal #2 is logically exclusive-ORed, it can then be expressed as follows.

#2($1)=211∘212∘213∘214∘215∘216 (2)

As for a supervisory frame $1 of the STS-1 signal #3, it can be expressed as:

#3($1)=311∘312∘313∘314∘315∘316 (3)

In the present embodiment, a logical exclusive-OR operation is performed for each supervisory frame according to above equations (1) to (3). The values stored in the F/Fs 8 to 10 are signals #1 to #3 as shown in FIG. 5.

Signal from the F/F 10 is output from the exclusive-OR (EX-OR) gate 13 as is. Output signal #3 of the EX-OR gate 13 is then supplied to the concatenation control circuit 16. Since the third STS-1 signal, that is, the STS-1 signal #3, is input to the concatenation control circuit 16, the output signal #3 of the EX-OR gate 13 is supplied to the EX-OR gate 12 as is.

The EX-OR gate 12 performs an exclusive-OR operation on the signals #2 and #3. The second STS-1 signal, the STS-1 signal #2, is input to the concatenation control circuit 15, therefore the output signal #12 of the EX-OR gate 12 is supplied to the EX-OR gate 11 as is. The EX-OR gate 11 performs an exclusive-OR operation on the signals #1 and #12 in the same manner as the EX-OR gates 12 and 13. Accordingly, a signal #11 is obtained as a result of the BIP-N calculation performed on the STS-3c concatenated signals. It should be noted that no connection is made to the output of the concatenation control circuit 14, therefore the circuit 14 has no effect on the operation of the BIP-N calculation apparatus.

According to the present embodiment, the concatenation control circuits 14 to 16 and the EX-OR gates 11 to 13 are connected in a concatenation manner, so that a calculation is also performed in a concatenation manner on the results of the BIP-N calculation circuits 5 to 7 with respect to the STS-1 signals #1 to #3. With this construction, the concatenated signals are subjected to a byte-interleaved separation to obtain STS-1 signals, and a BIP-N calculation is performed on each of the STS-1 signals, signals #1 to #3. It is thereby possible to execute the BIP-N calculation of the concatenated signals in a simple construction. In addition, the apparatus according to the present embodiment has a construction that can be easily expanded in conformity with the kind of concatenated signals.

In the above embodiment, description has been made with respect to the STS-3c concatenated signals. However, the apparatus according to the present embodiment can be prepared for other concatenated signals such as STS-12c, STS-48c, STS-192c, or the like.

In case of the above-mentioned STS-3c, the EX-OR gates 11 to 13 and concatenation control circuits 14 to 16 are arranged or placed at the subsequent stage of the F/Fs 8 to 10 as shown in FIG. 1. For STS-12c, EX-OR gates and concatenation control circuits should be arranged and concatenated with respect to 12 STS-1 signals.

In other words, to cope with concatenated signals up to STS-48c, EX-OR gates and concatenation control circuits should be arranged in a concatenation manner with respect to 48 STS-1 signals. This construction enables to deal with STS-1, STS-3c, STS-12c, and STS-48c concatenated signals. The same is true for STM (Synchronous Transport Module)-0, STM-1, STM-4c, STM-16c, STM-64c, or the like, of the SDH.

What is claimed is:

1. A Bit Interleaved Parity (BIP)-N (N is an integer) calculating apparatus comprising:
separating means for performing a byte-interleaved separation on concatenated signals with respect to input synchronous transport signals to obtain a plurality of signals separated by the byte interleaving;
a plurality of BIP-N calculating circuits for executing a bit interleaved parity (BIP)-N calculation on each of said plurality of signals; and
a logical operation means for carrying out a logical operation on each calculation result of said plurality of BIP-N calculating circuits.

2. A BIP-N calculating apparatus according to claim 1, wherein said separating means includes serial/parallel conversion circuits for performing a serial/parallel conversion on said concatenated signals with respect to synchronous transport signals.

3. A BIP-N calculating apparatus according to claim 2, further including a plurality of separating means arranged at the preceding stage of each of said plurality of BIP-N calculating circuits in conformity with each of a plurality of signals which have been subjected to a byte-interleaved separation by said serial/parallel conversion circuits, for performing a bit-interleaved separation on a corresponding signal of said plurality of signals.

4. A BIP-N calculating apparatus according to claim 3, wherein said logical operation means further comprising; a plurality of exclusive-OR circuits for performing an exclusive-OR operation on calculation results of each of said plurality of BIP-N calculating circuits; and
a plurality of control circuits for passing through the results of said exclusive-OR operation with respect to a corresponding signal of each of said plurality of signals which have been subjected to a byte-interleaved separation,
wherein each of said plurality of exclusive-OR circuits and said plurality of control circuits are concatenated so as to perform a calculation in a concatenation manner on the results of said plurality of BIP-N calculation circuits.

5. A BIP-N calculating apparatus according to claim 4, wherein said synchronous transport signal is any one of STS (Synchronous Transport Signal)-1, STS-3c, STS-12c, STS-48c, and STS-192c concatenated signals, and STM (Synchronous Transport Module)-0, STM-1, STM-4c, STM-16c, and STM-64c concatenated signals.

6. A Bit Interleaved Parity (BIP)-N (N is an integer) calculating method, comprising the steps of:
performing a byte-interleaved separation on concatenated signals with respect to input synchronous transport signals to obtain a plurality of signals separated by the byte interleaving;
executing a bit interleaved parity (BIP)-N calculation on each of said plurality of signals; and
carrying out a logical operation on the results of said BIP-N calculation.

7. A Bit Interleaved Parity (BIP)-N calculating method according to claim 6, wherein the byte-interleaved separation is achieved by a serial/parallel conversion on said concatenated signals with respect to synchronous transport signals.

8. A Bit Interleaved Parity (BIP)-N calculating method according to claim 7, further including a step of performing, at the preceding stage of said BIP-N calculation, a bit-interleaved separation on each of a plurality of signals which have been subjected to a byte-interleaved separation.

9. A Bit Interleaved Parity (BIP)-N calculating method according to claim 8, wherein said logical operation includes a plurality of exclusive-OR operations performed on the calculation results of said BIP-N calculation; and a plurality of control operations for passing through the results of said exclusive-OR operations with respect to a corresponding signal of each of said plurality of signals which have been subjected to a byte-interleaved separation,
wherein said plurality of exclusive-OR operations and said plurality of control operations are linked so as to perform a calculation in a concatenation manner on the results of said BIP-N calculation.

10. A Bit Interleaved Parity (BIP)-N calculating method according to claim 8, wherein said synchronous transport signal is any one of STS (Synchronous Transport Signal)-1, STS-3c, STS-12c, STS-48c, and STS-192c concatenated signals, and STM (Synchronous Transport Module)-0, STM-1, STM-4c, STM-16c, and STM-64c concatenated signals.
